(19) United States
(12) Patent Application Publication
(10) Pub. No.: US 2025/0022743 A1
(43) Pub. Date: Jan. 16, 2025

(54) COLLET STRUCTURE AND SEMICONDUCTOR FABRICATING APPARATUS INCLUDING THE SAME

(71) Applicants: SK hynix Inc., Gyeonggi-do (KR); FLC, Chungcheongnam-do (KR)

(72) Inventors: Taek Sang NAM, Gyeonggi-do (KR); Jae Young YU, Gyeonggi-do (KR); Jung Bum WOO, Gyeonggi-do (KR)

(21) Appl. No.: 18/900,931

(22) Filed: Sep. 30, 2024

Related U.S. Application Data
(63) Continuation-in-part of application No. 17/242,996, filed on Apr. 28, 2021, now Pat. No. 12,106,996.

(30) Foreign Application Priority Data
Oct. 8, 2020 (KR) 10-2020-0130330

(51) Int. Cl. H01L 21/683

(52) U.S. Cl. CPC H01L 21/6838

(57) ABSTRACT

A collet structure may include a holder, a plate and an absorption member. The holder may include a shank and a vacuum provider. The shank may include a first magnet. The vacuum provider may be positioned over the shank. The vacuum provider may include at least one first vacuum hole configured to transfer vacuum, which may be supplied from the outside, to a space under the shank. The plate may have a size substantially the same as a size of the shank. The plate may include a plurality of second vacuum holes connected directly and indirectly to the first vacuum hole. The absorption member may be attached to the plate. The absorption member may include a plurality of third vacuum holes connected directly and indirectly to the plurality of second vacuum holes.

### CROSS-REFERENCE TO RELATED APPLICATIONS

The present application is a Continuation-In-Part application of U.S. patent application Ser. No. 17/242,996 filed on Apr. 28, 2021, which claims priority under 35 U.S.C. § 119(a) to Korean application number 10-2020-0130330, filed on Oct. 8, 2020, which is incorporated herein by reference in its entirety.

### BACKGROUND

### 1. Technical Field

Various embodiments of the present invention generally relate to a semiconductor fabricating system and, more particularly, to a collet structure for a pick-up of a semiconductor chip. Various embodiments of the present invention relate also to a semiconductor fabricating apparatus including the collet structure.

### 2. Related Art

Generally, semiconductor devices may be integrated on a semiconductor substrate by repeatedly performing a series of semiconductor fabrication processes. The semiconductor substrate (i.e., semiconductor wafer) may include a plurality of semiconductor chips or semiconductor dies. After completing the semiconductor fabricating processes, the semiconductor substrate may be singulated into the semiconductor chips. The process for singulating the semiconductor chips may be referred to as a dicing process. The singulated semiconductor chips may be bonded to a package substrate.

The semiconductor chips separated from the semiconductor substrate may be picked up by a collet of a transferring apparatus or a die bonding apparatus. The semiconductor chips picked up by the collet may be transferred to the package substrate.

The collet may include a plurality of parts. It may be required to periodically exchange the parts for new parts. Thus, a collet having a simple structure may be required. Further, because the collet may pick up the semiconductor chips one-by-one, interference between the semiconductor chip picked up by the collet and an adjacent semiconductor chip or other parts may be generated. In order to prevent a collision between the semiconductor chip picked up by the collet and the adjacent semiconductor chip or the adjacent parts, a collet having a simple structure may be required.

### SUMMARY

In various embodiments of the present disclosure, a collet structure may include a holder, a plate and an absorption member. The holder may include a shank and a vacuum provider. The shank may include a first magnet. The vacuum provider may be positioned over the shank. The vacuum provider may include at least one first vacuum hole configured to transfer vacuum, which may be supplied from the outside, to a space under the shank. The plate may have a size substantially the same as a size of the shank. The plate may include a plurality of second vacuum holes connected directly and indirectly to the first vacuum hole. The absorption member may be attached to the plate. The absorption member may include a plurality of third vacuum holes connected directly and indirectly to the plurality of second vacuum holes.

In various embodiments of the present disclosure, a semiconductor fabricating apparatus is provided including a collet structure configured to pick-up a semiconductor die. The collet structure may include a holder, a plate and an absorption member. The holder may include a shank and a vacuum provider. The shank may include a first magnet and an edge contact. The edge contact may extend downwardly on a selected region of a pair of parallel edge regions. The vacuum provider may be positioned over the shank to receive vacuum from the outside. The plate may include sidewalls and an edge groove. The sidewalls may be coincided with sidewalls of the shank. The edge groove may be configured to receive the edge contact. The absorption member may be attached to the plate to absorb the semiconductor die using the vacuum.

In various embodiments of the present disclosure, a semiconductor fabricating apparatus is provided including a collet structure configured to pick-up a semiconductor die. The collect structure may include a holder, a plate and an absorption member. The holder may include a shank and a vacuum provider. The shank may include a first magnet and an edge contact. The edge contact may extend downwardly on a selected region of a pair of parallel edge regions. The vacuum provider may be positioned over the shank. The vacuum provider may include at least one first vacuum hole configured to receive vacuum from the outside. The plate may include sidewalls, an edge groove, a second magnet and a plurality of second vacuum holes. The sidewalls may be coincided with sidewalls of the shank. The edge groove may be configured to receive the edge contact. The second magnet may be magnetically combined with the first magnet. The plurality of second vacuum holes may transfer the vacuum to a region in which the second magnet may be located. The absorption member may be attached to the plate to absorb. The absorption member may include a plurality of third vacuum holes connected to the plurality of second vacuum holes. A lower surface of the shank where the first vacuum hole may be positioned, upper and lower surfaces of the plate where the plurality of second vacuum holes may be positioned, and an upper surface of the absorption member where the plurality of third vacuum holes may be positioned may have a flat surface.

In various embodiments of the present disclosure, a collet structure for a semiconductor manufacturing apparatus, the collet structure may comprise a holder and a plate. The holder includes a first vacuum hole passing through a central section of the holder, and a magnetic shank surrounding the holder. The plate is configured to be coupled with the holder. The plate includes a second vacuum hole in fluid communication with the first vacuum hole when the plate is coupled to the holder for transferring a vacuum to an absorption member to hold the absorption member attached to the plate. The holder has an alignment block for aligning the holder with the plate. The plate is coupled to the holder magnetically via a magnetic force exerted by the magnetic shank.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is an exploded perspective view illustrating a collet structure in accordance with an embodiment of the present disclosure;

FIG. 2 is a side view illustrating a collet structure in accordance with an embodiment of the present disclosure;

FIG. 3 is a cross-sectional view illustrating a holder of a collet structure in accordance with an embodiment of the present disclosure;

FIGS. 4A and 4B are bottom views illustrating a holder in accordance with embodiments of the present disclosure;

FIGS. 5A to 5E are plan views illustrating arrangements of a magnet in accordance with embodiments of the present disclosure;

FIG. 6 is a cross-sectional view illustrating a plate in accordance with an embodiment of the present disclosure;

FIGS. 7A and 7B are top views illustrating a plate in accordance with embodiments of the present disclosure;

FIG. 8 is a cross-sectional view illustrating an absorption member in accordance with an embodiment of the present disclosure;

FIG. 9 is a plan view illustrating an absorption member in accordance with an embodiment of the present disclosure;

FIGS. 10 and 11 are cross-sectional views a method of dissembling a collet structure in accordance with embodiments of the present disclosure;

FIG. 12 is a cross-sectional view illustrating a collet structure in accordance with an embodiment of the present disclosure;

FIGS. 13 and 14 are cross-sectional views illustrating operations for picking-up a semiconductor chip by a collet structure in accordance with embodiments of the present disclosure;

FIG. 15 is an exploded perspective view illustrating a collet structure in accordance with example embodiments;

FIG. 16 is a bottom view illustrating a shank in FIG. 15;

FIG. 17 is a plan view illustrating a plate in FIG. 15;

FIG. 18 is a bottom view illustrating an absorption member in FIG. 15; and

FIG. 19 is a cross-sectional view illustrating a collet structure in accordance with example embodiments.

### DETAILED DESCRIPTION

Various embodiments of the present invention will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein with reference to cross-section and/or plan illustrations of embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and spirit of the present invention.

Hereinafter, terms such as a semiconductor wafer, a wafer, a substrate, a wafer substrate, a partially fabricated integrated circuit, etc., may be interchangeably used with each other. However, the substrate may indicate the semiconductor wafer, a chamber component processed in different reaction chamber, or a package substrate. A person skilled in the art may understand the partially fabricated integrated circuit as a silicon wafer during an arbitrary process among semiconductor fabricating processes.

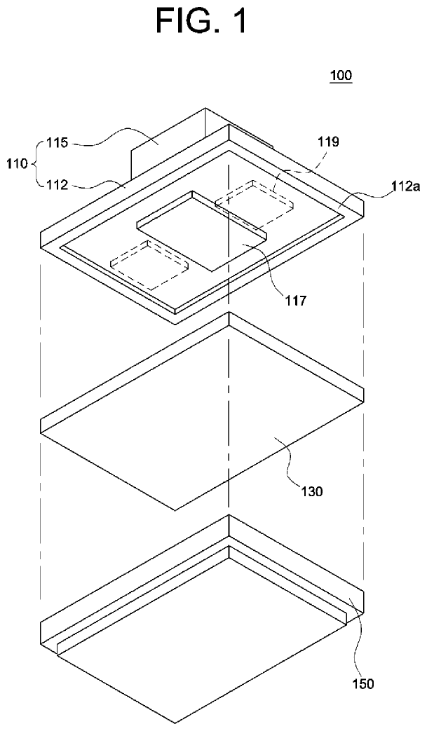

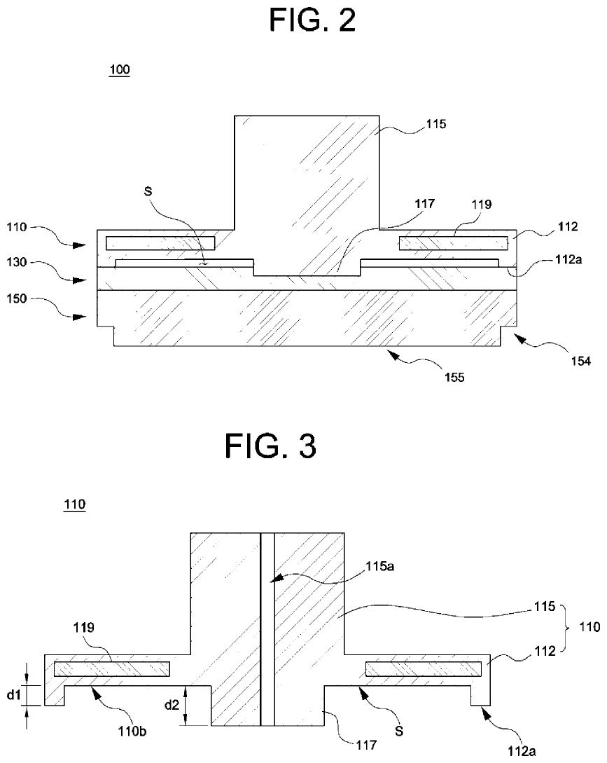

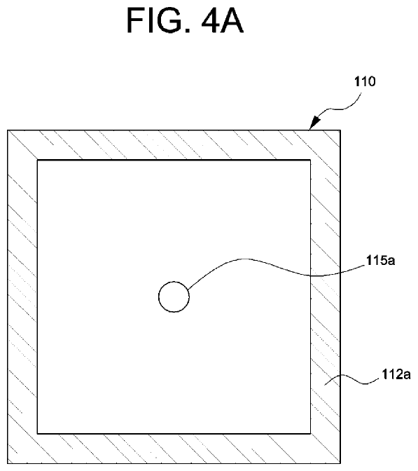

FIG. 1 is an exploded perspective view illustrating a collet structure in accordance with an embodiment of the present disclosure, FIG. 2 is a side view illustrating a collet structure in accordance with an embodiment of the present disclosure, and FIG. 3 is a cross-sectional view illustrating a holder of a collet structure in accordance with an embodiment of the present disclosure.

Referring to FIGS. 1 to 3, a collet structure 100 of a semiconductor fabricating apparatus in accordance with an embodiment may include a holder 110, a plate 130 and an absorption member 150.

The holder 110 may be configured to fix the plate 130 and the absorption member 150. For example, the plate 130 may be magnetically fixed to the holder 110. The holder 110 may have a size substantially equal to or less than a size of the plate 130. The holder 110 may include a shank 112 and a vacuum provider 115. The shank 112 and the vacuum provider 115 may be integrally formed with each other. The shank 112 and the vacuum provider 115 may be formed of the same or substantially the same material. The shank 112 may have a plate shape having a uniform thickness. The shank 112 may be configured to make contact with the plate 130. Thus, the shank 112 may have an area substantially equal to or less than an area of the plate 130.

The vacuum provider 115 may receive vacuum from an external device outside the holder 110. For example, the vacuum provider 115 may be positioned on a central portion of an upper surface of the shank 112. The vacuum provider 115 may include a first vacuum hole 115a formed in the vacuum provider 115. The first vacuum hole 115a may be extended to a bottom surface 110b of the holder 110 to transfer the vacuum to the plate 130 and the absorption member 150.

Forming the shank 112 and the vacuum provider 115 of the holder 110 as an integral part from the same material is advantageous because it is not required to perform an additional process for aligning the shank 112 with the vacuum provider 115. In an embodiment, the shank 112 and the vacuum provider 115 may be formed of or include a non-conductive rubber, silicon, a urethane, and the like.

The shank 112 may include an edge contact 112a formed at an edge portion of a bottom surface of the shank 112. The edge contact 112a may have the shape of a rectangular protrusion having a first length d1 extending from the bottom surface 110b of the holder 110, in a side view. The edge contact 112a may be configured to make contact with the plate 130.

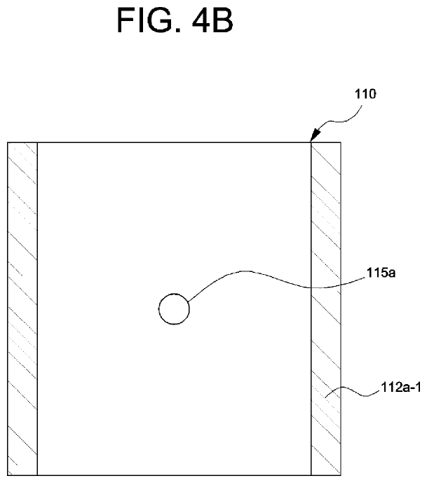

FIGS. 4A and 4B are bottom views illustrating a holder in accordance with embodiments of the present disclosure.

Referring to FIG. 4A, the edge contact 112a may have a frame shape configured to surround an edge portion of the bottom surface 110b of the holder 110. For example, a width of the edge contact 112a may be 1% to 10% of a width of the holder 110.

Alternatively, referring to FIG. 4B, an edge contact 112a-1 may be formed along a pair of opposite side surfaces of the bottom surface 110b of the holder 110. However, the edge contact 112a formed at the bottom surface of the holder 110 may have various shapes besides above-mentioned shapes.

Referring again to FIGS. 1 to 3, the holder 110 may further include an alignment block 117 used for mechanically combining the plate 130 with the holder 110. The alignment block 117 may be positioned on a central portion of the bottom surface 110b of the holder 110. The alignment block 117 may protrude by a second length d2 below the bottom surface 110b of the holder 110. The second length d2 may be longer than the first length d1. For example, the alignment block 117 may be located at a position corresponding to the vacuum provider 115. The alignment block 117 may have a diameter substantially equal to or less than a diameter of the vacuum provider 115. The first vacuum hole 115a may be extended to a bottom surface of the alignment block 117. In an embodiment, the alignment block 117 may be formed of or include a material substantially the same as the material of the shank 112 and the vacuum provider 115. In other words, the shank 112 and the vacuum provider 115 may form a single body. In an embodiment, one first vacuum hole 115a may be extended in the alignment block 117. In an embodiment, (not shown), the first vacuum hole 115a extended from the vacuum provider 115 may be branched into a plurality of vacuum lines in the alignment block 117.

The holder 110 may include at least one magnet 119. The magnet 119 may be arranged in the holder 110. The magnet 119 may be used for magnetically combining the holder 110 with the plate 130. In an embodiment, the magnet 119 may be formed of or include a material different from the material of the holder 110, i.e., the material of the shank 112, the vacuum provider 115 and the alignment block 117. In the illustrated embodiment, the at least one magnet 119 may have a plate shape and may be included only inside the shank 112 as shown in FIG. 3. The at least one magnet 119 may have various shapes.

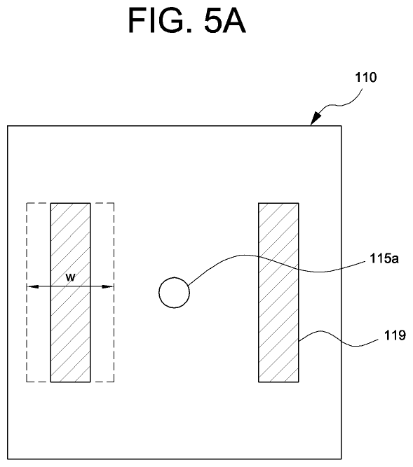

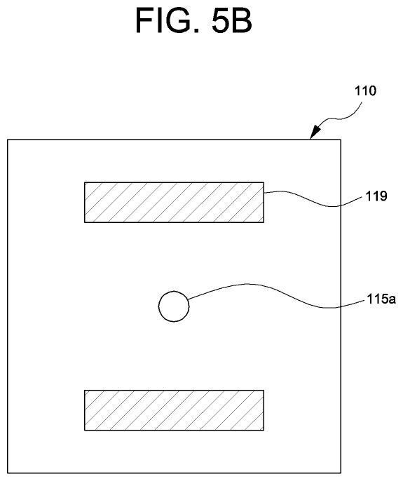

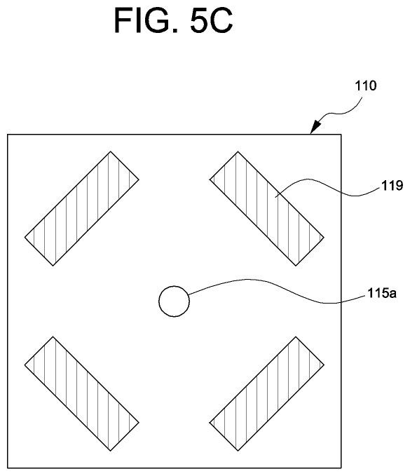

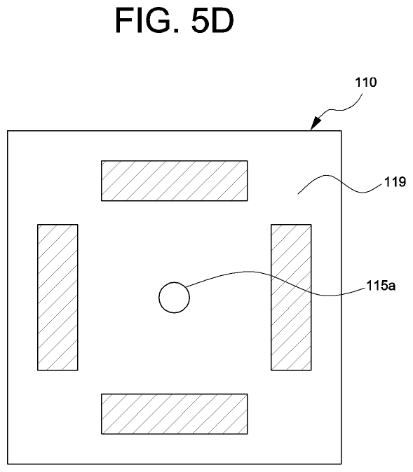

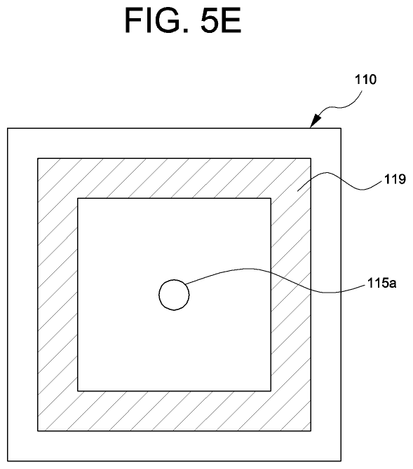

FIGS. 5A to 5E are plan views illustrating arrangements of a magnet in accordance with embodiments of the present disclosure.

Referring to FIGS. 5A and 5B, the magnet 119 may be arranged along two strips parallel to each other positioned on opposite sides of the holder 110. The vacuum hole 115a may be centrally positioned between the opposite strips of the magnet 119. Referring to FIG. 5C, the magnet 119 may be arranged at two or four strips positioned at opposite corners of the holder 110 with the vacuum hole 115a positioned centrally between the opposite strips of the magnet 119. Referring to FIG. 5D, the magnet 119 may be arranged at four strips positioned at the four side surfaces of the holder 110, respectively. Referring to FIG. 5E, the magnet 119 may have a frame shape. The magnet 119 in the example of FIG. 5E has a rectangular shape, however, the invention may not be limited in shape. For example, in another embodiment, not shown, the magnet 119 may have a ring shape.

The magnet 119 in FIGS. 5A to 5E may have a width w which may vary in accordance with the sizes of the holder 110 and the plate 130.

The magnet 119 may include, for example, a neodymium permanent magnet, an electromagnet, a combination of a permanent magnet and an electromagnet, etc., not restricted within any specific type. That is, the magnet 119 may be formed of or include any suitable material providing a controllable magnetic force.

The holder 110 and the plate 130 may be combined with each other by the magnet 119 so that the plate 130 may be attached to the holder 110 without any slant.

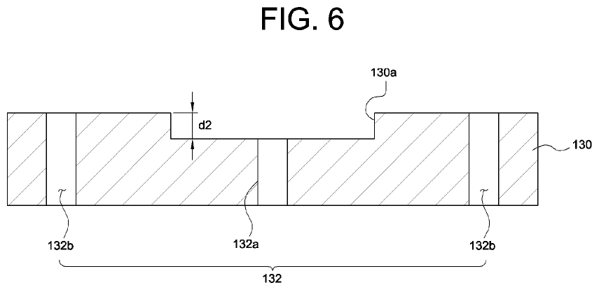

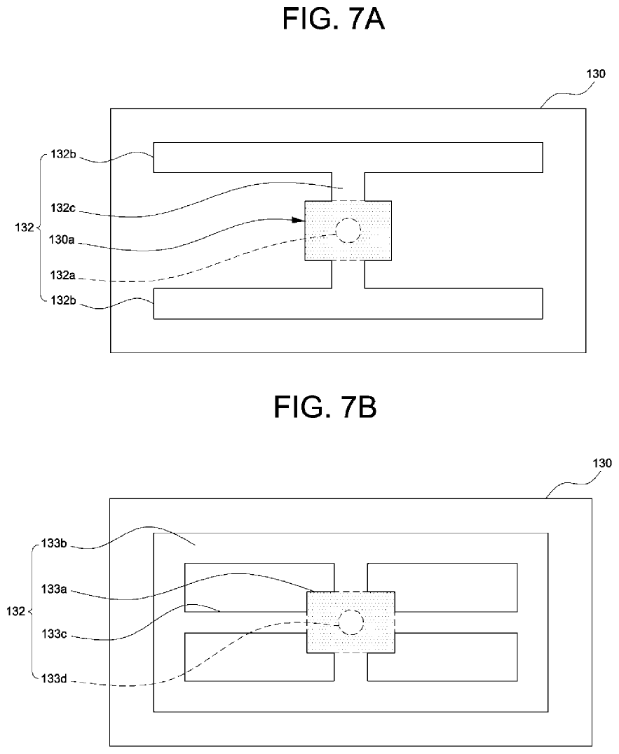

FIG. 6 is a cross-sectional view illustrating a plate in accordance with an embodiment of the present disclosure. FIGS. 7A and 7B are top views illustrating a plate in accordance with embodiments of the present disclosure.

Referring to FIGS. 1 to 7B, the plate 130 may include a alignment groove 130a configured to receive the alignment block 117. The alignment groove 130a may be formed at a central section of the top surface of the plate 130 that is positioned adjacent to the bottom surface of the holder 110. The alignment groove 130a may have a depth equal to or substantially equal to the second length d2. The plate 130 may be formed of or include a material magnetically combined with the holder 110 by the magnet 119. For example, the plate 130 may include a stainless component.

As mentioned above, when the plate 130 is attached to the holder 110, the edge contact 112a of the holder 110 may make contact with the upper surface of the plate 130. A space S may be formed between the edge contact 112a and the alignment block 117. The space S may function as a common vacuum space for absorbing the semiconductor chip during the vacuum provided from the vacuum provider 115.

The plate 130 may include a plurality of second vacuum holes 132 formed in the plate 130. The second vacuum holes 132 may be directly or indirectly connected to the first vacuum hole 115a to receive the vacuum.

As shown in FIG. 7A, the second vacuum holes 132 may include a center hole 132a, a line hole 132b and a connection hole 132c. The center hole 132a may be formed centrally within the alignment groove 130a and pass through the entire thickness of the plate 130. The center hole 132a may be located at a position aligning with the first vacuum hole 115a. Thus, the center hole 132a may be connected to the first vacuum hole 115a.

The line hole 132b may be extended along both long side surfaces of the plate 130 in parallel, with respect to the center hole 132a.

The connection hole 132c may extend between the line hole 132b and the alignment groove 130a to connect the line hole 132b and the alignment groove 130a. The vacuum supplied to the center hole 132a may be effectively transferred to the line hole 132b at the edge portion of the plate 130 through the connection hole 132c and the alignment groove 130a.

In another embodiment, as shown in FIG. 7B, a second vacuum hole 133 may include a center hole 133a, a line hole 133b and a connection hole 133c. The center hole 133a may be formed at a central portion of the plate 130. The line hole 133b may be formed along the edge portion of the plate 130. The connection hole 133c may be formed to connect the center hole 133a and the line hole 133b. The line hole 133b may have a rectangular frame shape configured to surround the four side surfaces of the rectangular plate 130. In this case, the four connection holes 133c may provide a connection between the center hole 133a and the four side surfaces of the rectangular frame.

Therefore, the vacuum supplied from the first vacuum hole 115a may be uniformly distributed to the plate 130 through the center hole 133a, the connection hole 133c and the line hole 133b.

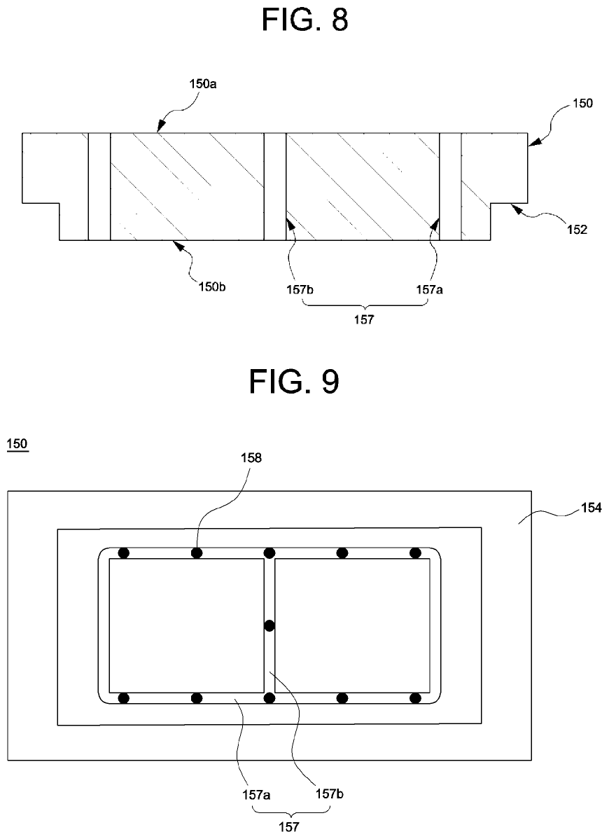

FIG. 8 is a cross-sectional view illustrating an absorption member in accordance with an embodiment of the present disclosure, and FIG. 9 is a plan view illustrating an absorption member in accordance with an embodiment of the present disclosure.

Referring to FIGS. 1 to 9, the absorption member 150 may include an upper surface 150a configured to make contact with the plate 130, and a bottom surface 150b facing a semiconductor chip (not shown). The absorption member 150 may be attached to the bottom surface of the plate 130 using: for example, an adhesive (not shown). The absorption member 150 may be formed of or include a resilient material for preventing the vacuum from being leaked through the absorption member 150. For example, the absorption member 150 may be formed of or include a rubber, silicon, and the like. Further, the absorption member 150 may include a conductive material for preventing generation of static electricity during the pick-up of the semiconductor chip. The absorption member 150 may have a thickness of about 3.5 mm to about 4 mm for minimizing an influence on other parts during the pick-up of the semiconductor chip.

A recess 154 may be formed at a lower corner of the absorption member 150. That is, the lower corner of the absorption member 150 may be removed to form the recess 154. The recess 154 may function to prevent a contact between the picked-up semiconductor chip and the adjacent semiconductor chip or a rail of the die bonding apparatus. The recess 154 may have a size changed in accordance with a size of the adjacent semiconductor chip, a size of the rail, etc. Further, when the absorption member 150 has a thin thickness, the absorption member 150 may not include the recess 154. For example, a sidewall of the recess 154 may correspond to an inner sidewall of the edge contact 112a.

The absorption member 150 may include a third vacuum hole 157. The third vacuum hole 157 may be connected to the second vacuum hole 132. The third vacuum hole 157 may be formed through the absorption member 150.

In various embodiments, the third vacuum hole 157 may include a first hole 157a and a second hole 157b. The first hole 157a may be configured to surround the absorption member 150. For example, the first hole 157a may have a frame shape. The second hole 157b may be configured to divide a space defined by the first hole 157a. For example, the first hole 157a may be connected to line holes 132b and 133b of the second vacuum holes 132 and 133. The first hole 157a may be formed at a position corresponding to the line holes 132b and 133b of the second vacuum holes 132 and 133. The second hole 157b may be connected to the center holes 132a and 133a and the connection holes 132c and 133c in the second vacuum holes 132 and 133.

The reference numeral 158 may indicate a tip formed at the third vacuum hole 157. The tip may be configured to make contact with the semiconductor chip. The tip may be formed of or include a rubber.

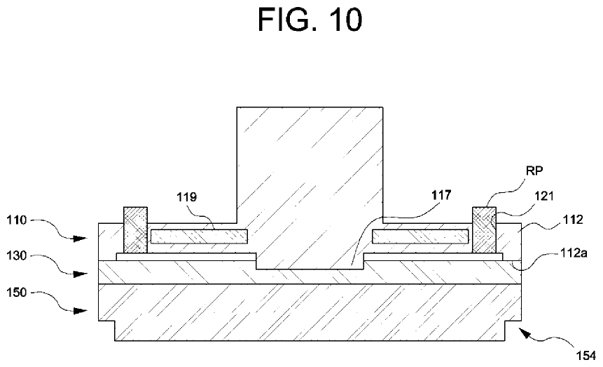

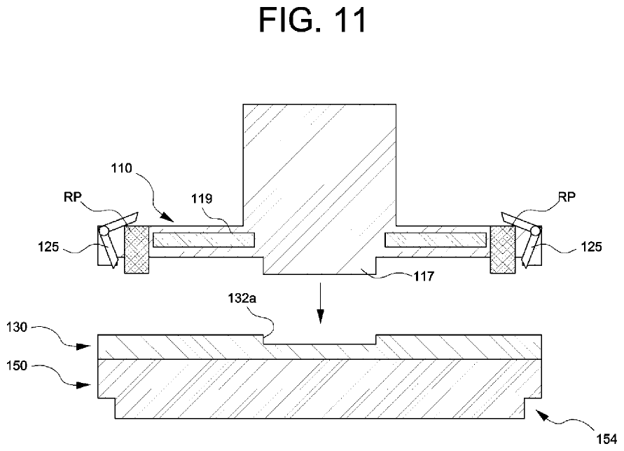

FIGS. 10 and 11 are cross-sectional views of a method of disassembling a collet structure in accordance with embodiments of the present disclosure.

Referring to FIGS. 10 and 11, a pin hole 121 may be formed at the shank 112. A removing pin RP may be inserted into the pin hole 121. The pin hole 121 may be formed at the edge portion of the shank 112 between the edge contact 112a and the magnet 119.

The pin hole 121 may be formed through the shank 112. The removing pin RP may have a length longer than a depth of the pin hole 121.

When the holder 110 is separated from the plate 130, the removing pin RP may be inserted into the pin hole 121. A latch 125 may be installed at the edge portion of the holder 110. A pressure may be applied to the removing pin RP using the latch 125 to separate the holder 110 from the plate 130.

Further, when the magnet 119 includes an electromagnet, the holder 110 may be more readily separated from the plate 130 by changing a magnetic force of the magnet 119. Alternatively, the holder 110 may be mechanically separated from the plate 130 using a mechanism such as a pneumatic cylinder.

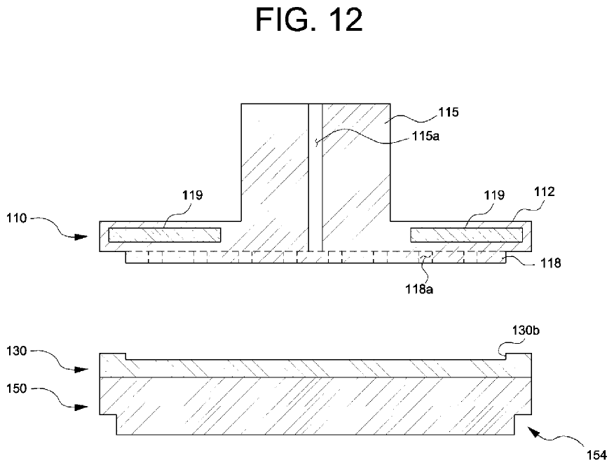

FIG. 12 is a cross-sectional view illustrating a collet structure in accordance with an embodiment of the present disclosure.

Referring to FIG. 12, the alignment block 118 may have a size larger than a size of the vacuum provider 115. For example, the size of the alignment block 118 may be overlapped with a part of the magnets 119 at both sides of the vacuum provider 115 as well as the vacuum provider 115. The alignment block 118 may be formed to extend along most of the region of the shank 112.

When the alignment block 118 occupies most of the region of the shank 112, a plurality of sub-vacuum holes 118a may be formed at the alignment block 118. The sub-vacuum holes 118a may be directly or indirectly connected to the first vacuum hole 115a. For example, the sub-vacuum holes 118a may be branched from the first vacuum hole 115a.

The plate 130 may include an alignment groove 130b configured to receive the alignment block 118. Thus, a side surface of the alignment block 118 and a side surface of the alignment groove 130b may be actual contact surfaces between the holder 110 and the plate 130.

Because the alignment groove 130b of the plate 130 may have an increased area, the number of the center holes may also be increased. For example, the number of the center holes in the alignment groove 130b may correspond to the numbers of the sub-vacuum holes 118a.

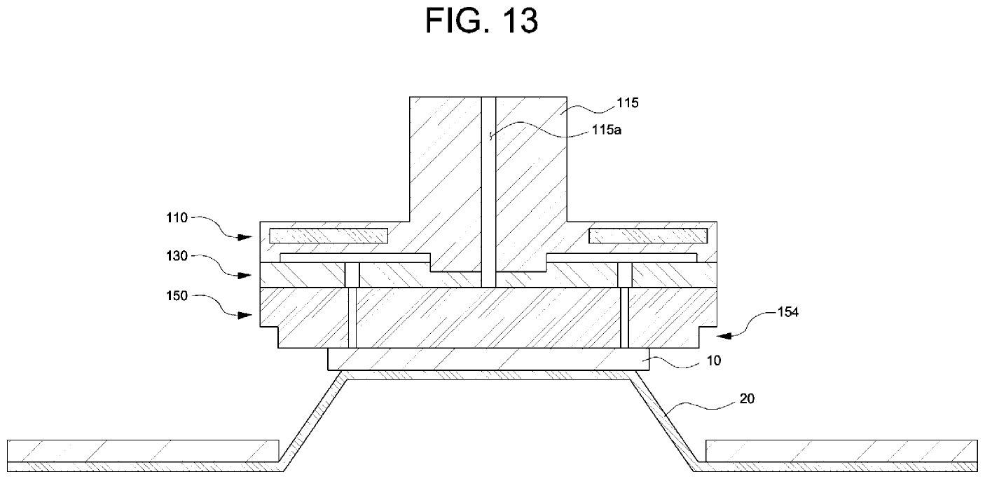

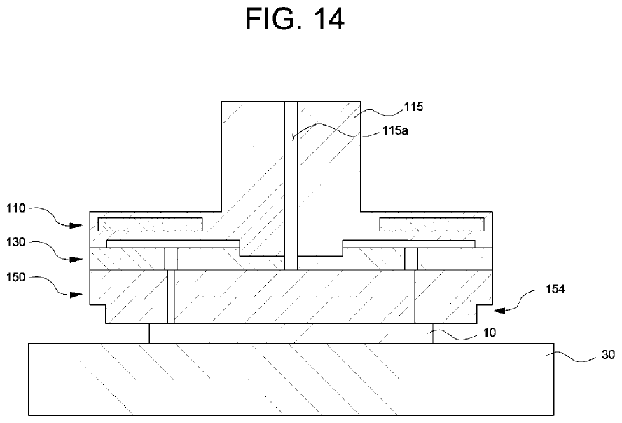

FIGS. 13 and 14 are cross-sectional views illustrating operations for picking-up a semiconductor chip by a collet structure in accordance with embodiments of the present disclosure.

Referring to FIGS. 13 and 14, the processes may be performed on the semiconductor substrate to form the plurality of the semiconductor chips 10. The semiconductor substrate may be cut along a scribe lane to singulate the semiconductor chips 10. The cut semiconductor chips 10 may be connected to each other using a tape.

The transferring apparatus may move the collet structure 100 over the semiconductor chip 10. The vacuum may then be applied to the collet structure 100. The vacuum may be supplied to the absorption member 150 through the first vacuum hole 115a, the second vacuum hole 132 and the third vacuum hole 157 to absorb the semiconductor chip 10 on the absorption member 150.

The absorption member 150 may have a sufficient thickness or the recess 154 may be formed a lower corner of the absorption member 150 so that a contact between the absorption member 150 and the adjacent semiconductor chip or the transferring apparatus such as the rail during the pick-up may be prevented. Further, because the holder 110 may be located over the plate 130, the holder 110 may not protrude from the side surface of the plate 130 to minimize the contact between the picked-up semiconductor chip and the parts of the transferring apparatus 200. Furthermore, because the holder 110 may make contact with the upper surface of the plate 130, the holder 110 may be configured to make contact with the plate 130 having various sizes to transfer the semiconductor chip having various sizes.

The semiconductor chip 10 absorbed on the collet structure 100 may be separated from the tape 20 by ejecting operation of the transferring apparatus 200.

The transferring apparatus 200 may attach the semiconductor chip 10 absorbed on the collet structure 100 to the upper surface of the package substrate 30. The transferring apparatus 200 may stop the supply of the vacuum to the collet structure 100 to complete the pick-up process and the transfer process of the collet structure 100.

According to various embodiments, the shank and a vacuum provider in the holder of the collet structure may be integrally formed with each other to omit an additional process for combining the vacuum provider with the shank. Further, the size of the holder may be substantially equal to or less than the size of the plate. Thus, the holder may make contact with the plates having various sizes to pick-up the semiconductor chips having various sizes. Furthermore, the semiconductor chip picked-up by the holder having a small size may not make contact with adjacent other semiconductor chips and/or parts. As a result, efficiency of a pick-up process, productivity of the semiconductor chip, etc., may be improved and a process error may also be prevented.

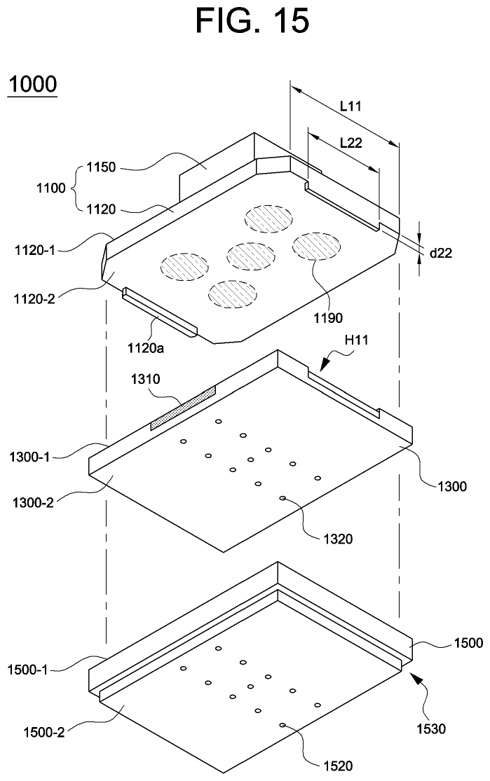

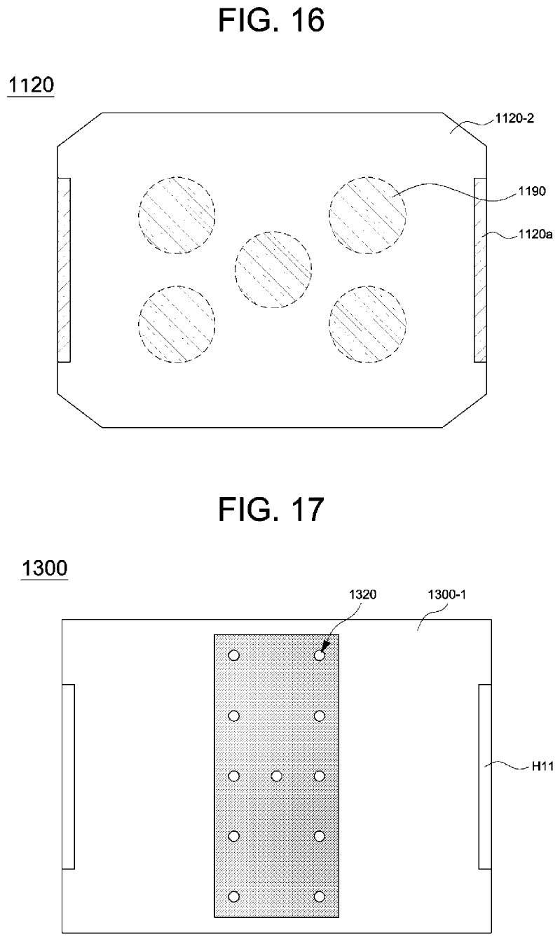

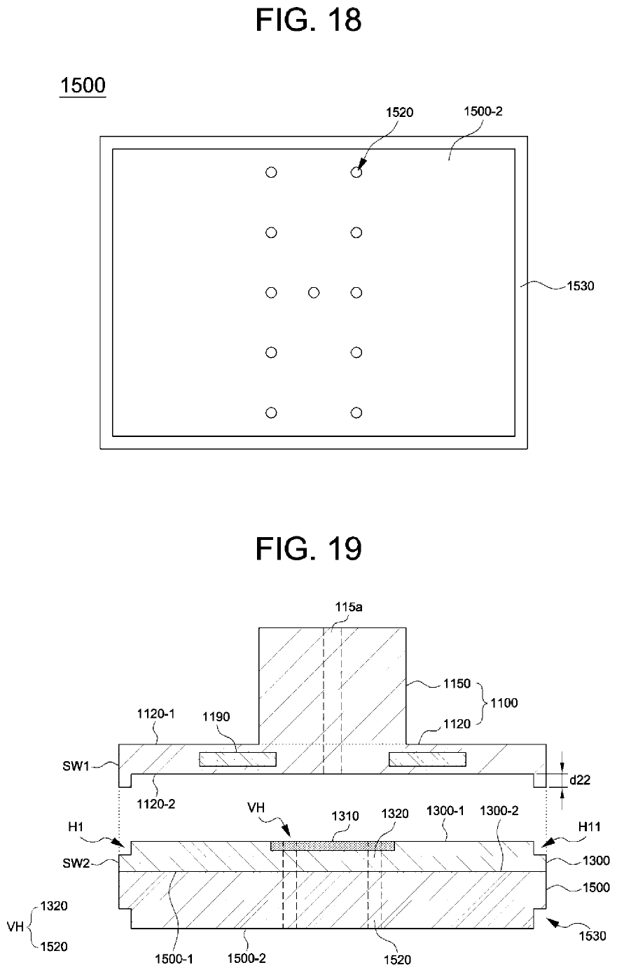

FIG. 15 is an exploded perspective view illustrating a collet structure in accordance with example embodiments, FIG. 16 is a bottom view illustrating a shank in FIG. 15, FIG. 17 is a plan view illustrating a plate in FIG. 15, FIG. 18 is a bottom view illustrating an absorption member in FIG. 15 and FIG. 19 is a cross-sectional view illustrating a collet structure in accordance with example embodiments.

Referring to FIGS. 15 to 19, a collet structure 100 of example embodiments may include a holder 1100, a plate 1300 and an absorption member 1500.

The holder 1100 may include a shank 1120 and a vacuum provider 1150 similarly to the structure in FIG. 1.

The shank 1120 may include an upper surface 1120-1 and a lower surface 1120-2. The lower surface 1120-2 of the shank 1120 may be attached to an upper surface 1300-1 of the plate 1300. The shank 1120 may have a size substantially the same as a size of the plate 1300. For example, a sidewall SW1 of the shank 1120 may be coincided with a sidewall SW2 of the plate 1300. Particularly, all the sidewall SW1 of the shank 1120 except for a corner of the shank 1120 may be coincided with all the sidewall SW2 of the plate 1300.

Further, the lower surface 1120-2 of the shank 1120 may have a quadrangular shape. In example embodiments, the lower surface 1120-2 of the shank 1120 may have a quadrangular shape including a chamfered corner. Further, the lower surface 1120-2 of the shank 1120 may have a flat surface except for a selected edge.

In example embodiments, the shank 1120 may include an edge contact 1120a positioned at a selected edge of the shank 1120. The edge contact 1120a may be arranged opposite to each other at parallel two edges among four edges of the shank 1120.

For example, when the shank 1120 may have a rectangular shape, the edge contact 1120a may be located at a short side of the shank 1120. A horizontal length L22 of the edge contact 1120a may be shorter than a length L11 of the short side of the shank 1120. The edge contact 1120a may extend by a first vertical length d22 toward a lower surface of the plate 1300.

A first magnet 1190 may be provided in the holder 1100, particularly, the shank 1120. The first magnet 1190 may have a plurality of circular shapes in FIG. 15, but is not limited thereto, various shapes.

The vacuum provider 1150 may have a configuration substantially the same as the configuration of the vacuum provider 115 of previous example embodiments. For example, the vacuum provider 1150 may include at least one first vacuum hole 115a as shown in FIG. 3. The vacuum provider 1150 may be formed integrally with the shank 1120 to form the holder 1100.

The plate 1300 may include the upper surface 1300-1 and the lower surface 1300-2. The upper surface 1300-1 of the plate 1300 may be attached to the lower surface 1200-2 of the shank 1200. In example embodiments, the size of the plate 1300 may be substantially the same as the size of the shank 1120. An edge groove H11 may be formed at a short side of the plate 1300 corresponding to the short side of the shank 1120. The edge groove H11 may have a size combined with the edge contact 1120a. The edge contact 1120a and the edge groove H11 may act as a combination guide configured to physically combine the shank 1120 with the plate 1300.

In example embodiments, the plate 1300 may include a second magnet 1310 magnetically combined with the first magnet 1190. The second magnet 1310 may be positioned at a central portion of the plate 1300. For example, the upper surface 1300-1 of the plate 1300 may be partially removed to form a space. The second magnet 1310 may be inserted into the space to form the plate 1300 with the second magnet 1310.

Alternatively, the second magnet 1310 may be built in the plate 1300.

Further, the plate 1300 may further include a plurality of second vacuum holes 1320 formed through the plate 1300. The plurality of second vacuum holes 1320 may be connected directly and indirectly to the first vacuum hole 115a to receive the vacuum. In cases, the plurality of second vacuum holes 1320 may be formed at a region where the second magnet 1310 may be positioned. That is, the second magnet 1310 and the plate 1300 under the second magnet 1310 may be etched to form the plurality of second vacuum holes 1310.

In example embodiments, the plate 1300 may include a stainless material. The plurality of second vacuum holes 1320 may be located at the central portion of the plate 1300, but is not limited thereto, arranged in various shapes. By arranging the first magnet 1190 and the second magnet 1310, the shank 1120 and the plate 1300 in the holder 1100 may be aligned with each other by the magnetic force.

The absorption member 1500 may include an upper surface 1500-1 and a lower surface 1500-2. The upper surface 1500-1 of the absorption member 1500 may be attached to the lower surface 1300-2 of the plate 1300.

The absorption member 1500 may include a plurality of third vacuum holes 1520 formed from the upper surface 1500-1 to the lower surface 1500-2 in the absorption member 1500. The plurality of third vacuum holes 1520 may be configured to receive the vacuum from the plurality of second vacuum holes 1320. In example embodiments, the plurality of third vacuum holes 1520 may be connected to the plurality of second vacuum holes 1320 to form a vertical vacuum hole VH. Thus, the plurality of third vacuum holes 1520 may fix the diced semiconductor die by the vacuum provided from the first vacuum hole 115a and the plurality of second vacuum holes 1320.

Further, the upper surface 1500-1 of the absorption member 1500 may be attached to the lower surface 1300-1 of the plate 1300 using an adhesive.

Furthermore, the absorption member 1500 may further include a recessed portion 1530 formed at an edge of the lower surface 1500-2 of the absorption member 1500. When picking-up the semiconductor die, the recessed portion 1530 may function as to prevent a contact between the absorption member 1500 and other semiconductor dies or a rail of a die bonding apparatus. In example embodiments, the absorption member 1500 may include a rubber.

According to example embodiments, the edge contact and the edge groove as the guide for combining the shank with the plate may be arranged at the selected portions of the shank and the plate. Thus, the lower surface of the shank, the upper and lower surfaces of the plate and the upper surface of the absorption member, which may be connected directly and indirectly with each other and may include the first to third vacuum holes, may have the flat surfaces. As a result, an interference element between the upper and lower vacuum holes may be removed to prevent a vacuum leak.

Further, after forming the space in the plate, the second magnet may be inserted into the space so that the second magnet may be formed without increasing a thickness of the plate. Furthermore, because the lower surface of the shank, the upper and lower surfaces of the plate and the upper surface of the absorption member may have the flat surfaces, various holders and various plates may be compatible with each other.

The above described embodiments of the present invention are intended to illustrate and not to limit the present invention. Various alternatives and equivalents are possible. The invention is not limited by the embodiments described herein. Nor is the invention limited to any specific type of semiconductor device. Other additions, subtractions, or modifications which are obvious in view of the present disclosure are intended to fall within the scope of the appended claims.

What is claimed is:

1. A collet structure comprising:
a holder including a shank and a vacuum provider positioned over the shank, the shank including a first magnet, and the vacuum provider including at least one first vacuum hole configured to transfer vacuum, which is provided from the outside, to a space under the shank;
a plate having a size substantially the same as a size of the shank, the plate including a plurality of second vacuum holes directly and indirectly connected to the first vacuum hole; and
an absorption member attached to the plate, the absorption member including a plurality of third vacuum holes connected directly and indirectly to the plurality of second vacuum holes,
wherein each of the shank and the plate comprises a combination guide provided to a selection region of a pair of parallel edges.

2. The collet structure of claim 1, wherein the combination guide comprises:
an edge contact protruding from a lower surface of the shank toward the plate; and
an edge groove formed at an edge of an upper surface of the plate,
wherein the edge groove has a depth substantially the same as a vertical length of the edge contact.

3. The collet structure of claim 2,
wherein the edge contact has a horizontal length substantially the same as a horizontal length of the edge groove, and
wherein the horizontal length of the edge contact is shorter than a length of the edge of the shank.

4. The collet structure of claim 2,
wherein the shank and the plate have a rectangular plane,
wherein the edge contact is positioned at a short side of the shank,
wherein the edge groove is positioned at a short side of the plate,
wherein a horizontal length of the edge contact is shorter than a length of the short side of the shank, and
wherein a horizontal length of the edge groove is substantially the same as the horizontal length of the edge contact and shorter than a length of the short side of the plate.

5. The collet structure of claim 4, wherein the shank has a chamfered rectangular plane.

6. The collet structure of claim 1, wherein a sidewall of the shank and a sidewall of the plate are positioned on a straight line.

7. The collet structure of claim 1, wherein a lower surface of the shank where the first vacuum hole is positioned, upper and lower surfaces of the plate where the plurality of second vacuum holes are positioned and an upper surface of the absorption member where the plurality of third vacuum holes are positioned have flat surfaces.

8. The collet structure of claim 1, further comprising a second magnet provided in the plate and magnetically combined with the first magnet.

9. The collet structure of claim 8, wherein an upper surface of the second magnet is substantially coplanar with an upper surface of the plate.

10. The collet structure of claim 8,
wherein the second magnet is positioned at a central portion of the plate, and
wherein the plurality of second vacuum holes are formed through the second magnet and the plate under the second magnet.

11. The collet structure of claim 1,
wherein the absorption member has an upper surface and a lower surface, and
wherein the absorption member comprises a recessed portion formed at an edge of the lower surface of the absorption member.

12. The collet structure of claim 11, wherein the absorption member comprises a rubber.

13. The collet structure of claim 1, wherein the plurality of second vacuum holes and the plurality of third vacuum holes are arranged opposite to each other.

14. A semiconductor fabrication apparatus including a collet structure configured to pick-up a semiconductor die,
the collet structure comprising:
a holder including a shank and a vacuum provider positioned over the shank, the shank including a first magnet and an edge contact downwardly extending on a selected region of a pair of parallel edges of the shank, and the vacuum provider configured to receive vacuum from the outside;
a plate including sidewalls and an edge groove, the sidewalls of the plate coincided with sidewall of the shank, and the edge grove configured to receive the edge contact; and
an absorption member attached to the plate to absorb the semiconductor die using the vacuum.

15. The semiconductor fabrication apparatus of claim 14,
wherein the vacuum provider comprises at least one first vacuum hole configured to transfer the vacuum,
wherein the plate comprises a plurality of second vacuum holes connected directly and indirectly to the first vacuum hole,
wherein the absorption member comprises a plurality of third vacuum holes connected to the plurality of second vacuum holes, and
wherein the vacuum provided to the vacuum provider is transferred to a lower surface of the absorption member through the first to third vacuum holes to fix the semiconductor die on the absorption member.

16. The semiconductor fabrication apparatus of claim 14, wherein a lower surface of the shank where the first vacuum hole is positioned, upper and lower surfaces of the plate where the plurality of second vacuum holes are positioned and an upper surface of the absorption member where the plurality of third vacuum holes are positioned have flat surfaces.

17. The semiconductor fabrication apparatus of claim 14,
wherein the shank and the plate have a rectangular plane,
wherein the edge contact is positioned at a short side of the shank,
wherein the edge groove is positioned at a short side of the plate,
wherein a horizontal length of the edge contact is shorter than a length of the short side of the shank, and
wherein a horizontal length of the edge groove is substantially the same as the horizontal length of the edge contact and shorter than a length of the short side of the plate.

18. The semiconductor fabrication apparatus of claim 14, further comprising a second magnet provided in the plate and magnetically combined with the first magnet.

19. The semiconductor fabrication apparatus of claim 14, wherein the shank and the vacuum provider are formed integrally with each other.

20. A semiconductor fabrication apparatus including a collet structure configured to pick-up a semiconductor die,
the collet structure comprising:
a holder including a shank and a vacuum provider positioned over the shank, the shank including a first magnet and an edge contact downwardly extending on a selected region of a pair of parallel edges of the shank, and the vacuum provider configured to receive vacuum from the outside;
a plate including sidewalls, an edge groove, a second magnet and a plurality of second vacuum holes, the sidewalls of the plate coincided with sidewall of the shank, the edge grove configured to receive the edge contact, the second magnet magnetically combined with the first magnet, and the plurality of second vacuum holes configured to transfer the vacuum to a region where the second magnet is positioned; and
an absorption member attached to the plate, the absorption member including a plurality of third vacuum holes connected to the plurality of second vacuum holes,
wherein a lower surface of the shank where the first vacuum hole is positioned, upper and lower surfaces of the plate where the plurality of second vacuum holes are positioned and an upper surface of the absorption member where the plurality of third vacuum holes are positioned have flat surfaces.
